(19) United States
(12) Patent Application Publication
(10) Pub. No.: US 2025/0167774 A1
(43) Pub. Date: May 22, 2025

(54) P-BIT GENERATOR AND METHODS FOR TUNING A P-BIT GENERATOR HAVING DECOUPLED STOCHASTIC AND CONTROL PATHS

(71) Applicant: King Fahd University of Petroleum and Minerals, Dhahran (SA)

(72) Inventors: Feras Mohamad Ameer AL-DIRINI, Dhahran (SA); Saleh Ahmad S BUNAIYAN, Goleta, CA (US)

(73) Assignee: King Fahd University of Petroleum and Minerals, Dhahran (SA)

(21) Appl. No.: 18/949,434

(22) Filed: Nov. 15, 2024

Related U.S. Application Data
(60) Provisional application No. 63/599,735, filed on Nov. 16, 2023.

(51) Int. Cl. H03K 3/84; H01F 10/32

(52) U.S. Cl. CPC H03K 3/84; H01F 10/3254

(57) ABSTRACT

A voltage divider for generating probabilistic bits (p-bits) through stochastic magnetic tunnel junction devices (sMTJs). The voltage divider comprises a first and a second sMTJ, each including a first and a second magnet separated by an insulator. A positive DC voltage (V_{DD}) is connected to the first electrical terminal of the first sMTJ, while a negative DC voltage (V_{SS}) is connected to the second electrical terminal of the second sMTJ. The p-bits randomly oscillate between resistance states in response to thermal noise. The voltage divider also includes a comparator with a non-inverting input, an inverting input connected to the p-bit output, a source, a drain, and an output terminal. The output voltage (Vₒᵤₜ) at the comparator is determined based on the resistances of the sMTJs.

### CROSS REFERENCE TO RELATED APPLICATIONS

The present application claims the benefit of priority to U.S. Prov. App. No. 63/599,735, entitled “MTJ-Based p-Bit Designs for Enhanced Tunability”, filed on Nov. 16, 2023, and incorporated herein by reference in its entirety.

### STATEMENT REGARDING PRIOR DISCLOSURE BY THE INVENTORS

Aspects of this technology are described in an article “P-Bit Design with Decoupled Stochastic And Control Paths”, presented at IEDM 2023 Special MRAM Poster Session, published on Dec. 12, 2023, which is incorporated herein by reference in its entirety.

### STATEMENT OF ACKNOWLEDGEMENT

Support provided by the King Fahd University of Petroleum and Minerals (KFUPM), Riyadh, Saudi Arabia through the Interdisciplinary Research Center for Advanced Materials (IRC-AM) under Grant No. INAM2306 is gratefully acknowledged.

### BACKGROUND

### Technical Field

The present disclosure is directed to a probabilistic computing device and system, specifically to a design of probabilistic-bit (p-bit) circuits with decoupled stochastic and control paths for enhanced tunability.

### Description of Related Art

The “background” description provided herein is for the purpose of generally presenting the context of the disclosure. Work of the presently named inventors, to the extent it is described in this background section, as well as aspects of the description which may not otherwise qualify as prior art at the time of filing, are neither expressly or impliedly admitted as prior art against the present invention.

Probabilistic computing is a field that seeks to bridge the gap between classical and quantum computing by introducing controlled randomness into computational processes. Traditional computing relies on deterministic logic, where binary states (0 and 1) represent information with predictable outcomes. Quantum computing, in contrast, uses quantum bits (qubits) capable of existing in superposition, enabling certain complex calculations to be solved more efficiently. Probabilistic computing introduces a distinct category, leveraging stochastic elements to create probabilistic behavior that uniquely benefits specific types of computational problems.

A key component of probabilistic computing is the probabilistic bit, or p-bit, first introduced in 2017. The p-bit functions similarly to a magnetic random access memory (MRAM) device but utilizes a stochastic magnetic tunnel junction (sMTJ) that fluctuates between resistance states due to thermal noise. This stochastic behavior allows p-bits to perform probabilistic operations, making them valuable for applications in optimization, machine learning, and encryption. The first successful implementation of p-bits was demonstrated in 2019, revealing their potential in addressing combinatorial optimization problems by efficiently sampling various solutions.

However, despite these promising capabilities, current p-bit designs face challenges. A primary limitation is a coupling between a stochastic path and a control path in existing p-bit circuits. The coupling creates interdependencies that make it challenging to independently manage stochastic behavior and activation functions of the circuit. As a result, the interdependencies can lead to reduced tunability, higher error rates, and inefficiencies in performing probabilistic computations.

US20220165933A1 describes a random number generator using an sMTJ and a comparator with a reference voltage applied to the non-inverting input. However, the random number generator does not consider replacing the reference voltage with an input voltage, which could potentially impact a tunability of the system.

US20140204661A1 describes a magnetic memory element utilizing two magnetic tunnel junctions (MTJs) programmed with complementary data. The magnetic memory element is primarily focused on memory applications, where the MTJs are stable and do not exhibit continuous stochastic fluctuations, thereby limiting their applicability in probabilistic computing.

Each of the aforementioned disclosures have limitations in providing effective control over the stochastic and control paths. The strong coupling between these paths in existing designs poses significant challenges, as it results in reduced flexibility and increased interference, making it difficult to achieve precise control over the probabilistic operations.

Therefore, there exists a need for a p-bit circuit design that effectively decouples the stochastic path from the control path, resulting in enhanced tunability and independent control of each component. Such a design would enable more robust and efficient implementations of probabilistic computing, providing improved scalability and adaptability for a wide range of computational tasks beyond memory-based applications.

### SUMMARY

In an exemplary embodiment, a voltage divider includes a first stochastic magnetic tunnel junction device and a second stochastic magnetic tunnel junction device. Each stochastic magnetic tunnel junction device includes a first magnet and a second magnet. The first magnet and the second magnet are separated by an insulator. A first electrical terminal is connected to the first magnet, and a second electrical terminal is connected to the second magnet. Each stochastic magnetic tunnel junction device is configured to generate probabilistic bits (p-bits) at a p-bit output terminal comprising the second electrical terminal of the first stochastic magnetic tunnel junction device and the first electrical terminal of the second stochastic magnetic tunnel junction device. The p-bits randomly oscillate between a first resistance state and a second resistance state in response to thermal noise.

The voltage divider further includes a positive DC voltage V_{DD} connected to the first electrical terminal of the first stochastic magnetic tunnel junction device, a negative DC voltage V_{SS} connected to the second electrical terminal of the second stochastic magnetic tunnel junction device, and a comparator including a non-inverting input terminal, an inverting input terminal, a source terminal and a voltage output terminal. The inverting terminal is connected to the p-bit output terminal and the non-inverting terminal is connected to a variable voltage V_{IN}.

A voltage Vₒᵤₜ at the voltage output terminal is given by:

$${V}_{out} = ( {V}_{D D} \cdot {R}_{MTJB} + {V}_{SS} \cdot {R}_{MTJT} ) / ( {R}_{MTJB +} {R}_{MTJT} ) ,$$

where R_{MTJB} is a resistance of the first stochastic magnetic tunnel junction device and R_{MTJT} is a resistance of the second stochastic magnetic tunnel junction device.

In another exemplary embodiment, a random number generator includes a stochastic device configured with a first electrical terminal, a second electrical terminal and a probabilistic bit (p-bit) output terminal. Each stochastic device is configured to generate p-bits at the p-bit output terminal which randomly oscillate between a parallel resistance state R_{P} and an anti-parallel resistance state R_{AP} in response to thermal noise.

The random number generator a positive DC voltage V_{DD} connected to the first electrical terminal of the stochastic device, a negative DC voltage V_{SS} connected to the second electrical terminal of the stochastic device, and an activation unit including a first input terminal, a second input terminal, an activation unit output terminal. The first input terminal is connected to the p-bit output terminal and the second input terminal is connected to a control unit. The activation unit is configured to generate a voltage output signal Vₒᵤₜ based on the resistance state of each p-bit upon receiving an input signal from the control unit.

In another exemplary embodiment a method of implementing a tunable probabilistic bit (p-bit) voltage divider includes connecting a first stochastic magnetic tunnel junction device to a second stochastic magnetic tunnel junction device, connecting a positive DC voltage V_{DD} to the first electrical terminal of the first stochastic magnetic tunnel junction device, and connecting a negative DC voltage V_{SS} connected to the second electrical terminal of the second stochastic magnetic tunnel junction device. Each stochastic magnetic tunnel junction device is configured to generate p-bits which randomly oscillate between a first resistance state and a second resistance state in response to thermal noise.

The method further includes generating, at a p-bit output terminal comprising the second electrical terminal of the first stochastic magnetic tunnel junction device and the first electrical terminal of the second stochastic magnetic tunnel junction device, p-bit output signals, and connecting an inverting terminal of a comparator to the p-bit output terminal.

The method further includes connecting the source terminal to the negative DC voltage V_{SS}, increasing a voltage of the variable voltage V_{IN} until the variable voltage V_{IN} is equal to a voltage received at the inverting terminal based on the p-bit output signals, and generating a voltage Vₒᵤₜ at the voltage output terminal given by:

$${V}_{out} = ( {V}_{D D} \cdot {R}_{MTJB} + {V}_{SS} \cdot {R}_{MTJT} ) / ( {R}_{MTJB +} {R}_{MTJT} ) ,$$

where R_{MTJB} is a resistance of the first stochastic magnetic tunnel junction device and R_{MTJT} is a resistance of the second stochastic magnetic tunnel junction device.

The foregoing general description of the illustrative embodiments and the following detailed description thereof are merely exemplary aspects of the teachings of this disclosure and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1A is a functional block diagram of a conventional probabilistic bit (p-bit) structure where a stochastic and a control path are coupled, according to certain embodiments.

FIG. 1B is a functional block diagram of a modified probabilistic bit (p-bit) structure where the stochastic path is decoupled from the control path, according to certain embodiments.

FIG. 2A is a functional block diagram of (1) a stochastic magnetic tunnel junction (sMTJ) with associated layers and applications and (II) the energy wells of the free and fixed (pinned) layers, according to certain embodiments.

FIG. 2B illustrates a simulation environment used to model a behavior of the sMTJ, according to certain embodiments.

FIG. 3A is a functional block diagram of a 1T1M probabilistic bit (p-bit) circuit.

FIG. 3B illustrates a response curve of the p-bit structure, according to certain embodiments.

FIG. 4A is a functional block diagram of a tunable decoupled probabilistic bit (p-bit) circuit using a continuous sMTJ device, according to certain embodiments.

FIG. 4B represents a simulation response curve of the tunable decoupled p-bit structure, according to certain embodiments.

FIG. 5A illustrates a stochastic response curve of the tunable decoupled p-bit structure, according to certain embodiments.

FIG. 5B illustrates fluctuation limits of a drain voltage for the tunable decoupled p-bit structure, according to certain embodiments.

FIG. 6A is a functional block diagram of a voltage divider, according to certain embodiments.

FIG. 6B illustrates a corresponding p-bit response curve of the voltage divider, according to certain embodiments.

FIG. 6C illustrates a random number generator, according to certain embodiments.

FIG. 7 illustrates an analytical limit for the voltage divider, according to certain embodiments.

FIG. 8 illustrates a comparative mapping of the average stochastic response of the voltage divider, according to certain embodiments.

### DETAILED DESCRIPTION

In the drawings, like reference numerals designate identical or corresponding parts throughout the several views. Further, as used herein, the words “a”, “an” and the like generally carry a meaning of “one or more”, unless stated otherwise.

Furthermore, the terms “approximately,” “approximate”, “about” and similar terms generally refer to ranges that include the identified value within a margin of 20%, 10%, or preferably 5%, and any values therebetween.

Aspects of this disclosure relate to a p-bit generator, a voltage divider, and a random number generator utilizing stochastic magnetic tunnel junction devices. The p-bit generator features a design with decoupled stochastic and control paths, enhancing tunability and enabling efficient p-bit generation. The voltage divider and random number generator also leverage these devices to achieve improved scalability and control, providing a robust foundation for probabilistic computing systems.

The present disclosure addresses the limitations of existing p-bit implementations, specifically a coupling between the stochastic path and the control path, which restricts tunability and scalability. By decoupling these paths, the present disclosure achieves independent operation, reducing interdependencies that lead to inefficiencies in conventional designs, resulting in fine control over the p-bit output and allowing multiple p-bits to be driven by a single stochastic unit, simplifying the overall system design.

The present disclosure includes a p-bit generator using stochastic magnetic tunnel junctions (sMTJs), configured to generate p-bits that randomly oscillate between resistance states due to thermal noise. The voltage divider and random number generator use sMTJs to produce variable outputs for probabilistic computation. Thus, the present disclosure facilitates efficient probabilistic computing and is suitable for applications such as temperature-dependent optimization problems, including simulated annealing and parallel tempering.

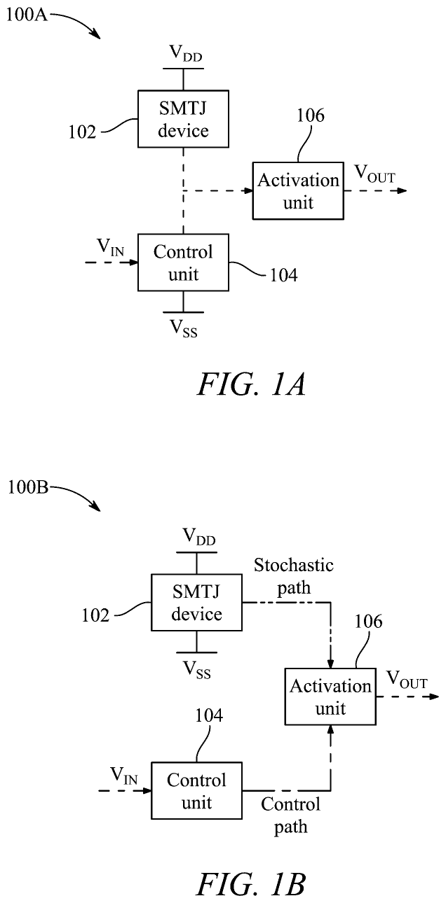

FIG. 1A illustrates a conventional probabilistic bit (p-bit) structure 100A where the stochastic and control paths are coupled. The p-bit structure includes a stochastic magnetic tunnel junction (sMTJ) 102, a control unit 104, and an activation unit 106.

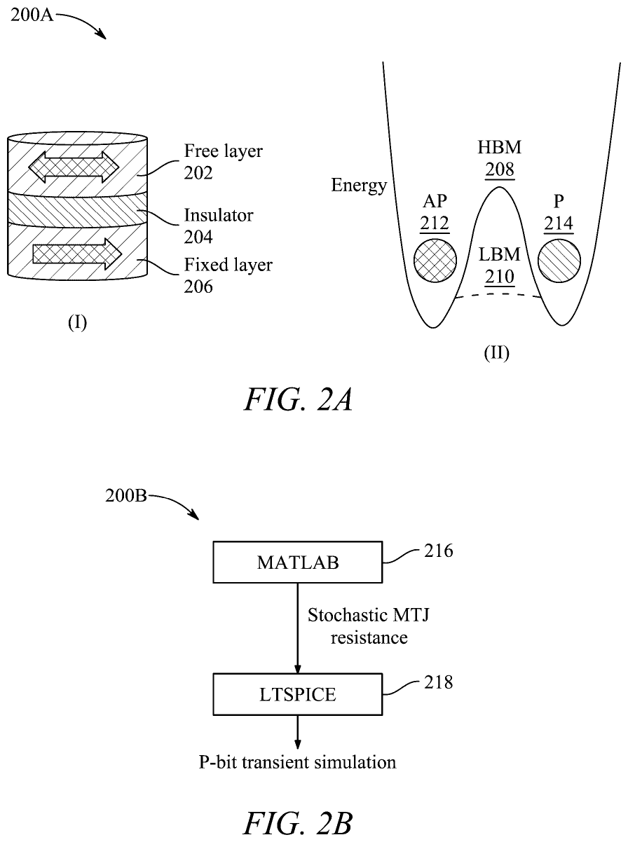

The stochastic magnetic tunnel junction (sMTJ) 102 is a type of magnetic tunnel junction (MTJ) device used in probabilistic computing implemented for stochastic computation. As shown in FIG. 2A(I), the sMTJ 102 consists of two ferromagnetic layers (202, 206) of different coercivities, which are separated by an insulating layer 204 called a tunnel barrier. In a non-limiting example, the ferromagnetic layers are made of cobalt iron, and the insulator is made of aluminum oxide. The two ferromagnetic layers can align in either parallel or anti-parallel configurations, leading to different electrical resistance states. The ferromagnetic layers are typically made of ferromagnetic materials, and the insulating tunnel barrier separates these layers, allowing quantum tunnelling to occur. Such tunnelling effect results in the stochastic switching behavior of the sMTJ 102, which is essential for generating probabilistic outputs. The sMTJ 102 fluctuates between a high resistance state, referred to as anti-parallel magnetization, and a low resistance state, referred to as parallel magnetization, in response to thermal noise, effectively generating a random bit that can be used in probabilistic computing applications.

The control unit 104 is connected in series with the sMTJ 102 for modulating the current passing through the sMTJ 102. The control unit 104 is typically an n-type or p-type field-effect transistor (FET) that allows the current flow through the sMTJ 102 to be controlled by adjusting the gate voltage applied to the transistor. Such adjustment enables the tuning of the current through the stochastic device, which in turn affects the switching probability of the sMTJ 102. The gate terminal of the control unit 104 acts as a control input, determining the operating point of the sMTJ and thereby coupling the control and stochastic paths of the circuit.

In the conventional p-bit structure 100A, the stochastic path, represented by the sMTJ 102, and the control path, governed by the control unit 104, are coupled. Such coupling means that any adjustment to the control unit, such as changing the gate voltage, directly affects the behavior of the sMTJ. While the structure 100A allows for basic stochastic behavior, it also imposes significant limitations. Specifically, the coupling of the stochastic and control paths leads to interdependencies that restrict the flexibility of the system. For example, increasing the current through the sMTJ to enhance its switching speed may simultaneously reduce the stochasticity, as the control path influences both the current level and the stochastic response of the sMTJ.

Such interdependencies limit the ability to independently tune the stochastic properties of the p-bit, making it challenging to achieve desired probabilistic characteristics without affecting other aspects of the circuit. This lack of independent tunability ultimately impacts the scalability and efficiency of probabilistic computations, especially in applications that require precise control over the stochastic response, such as probabilistic neural networks or hardware-based Ising machines. The coupled design also poses challenges in scaling the circuit for larger, more complex probabilistic systems, where independent tuning of each component is crucial for achieving optimal performance.

FIG. 1B illustrates a modified probabilistic bit (p-bit) structure 100B, where the stochastic path is decoupled from the control path. Decoupling refers to the separation of the stochastic behavior from the control elements, allowing each path to be independently controlled without mutual interference. In the modified p-bit structure 100B, the stochastic magnetic tunnel junction (sMTJ) 102 is decoupled from the control unit 104, which enables independent adjustments of both paths, significantly improving the flexibility and tunability of the circuit.

The sMTJ 102 operates as the stochastic element, where its behavior is influenced by thermal noise, producing probabilistic bit outputs. The control unit 104 is configured for managing the input control voltage, which no longer directly influences the stochastic path. As a result of decoupling, the stochastic behavior is controlled independently of the control voltage applied to the system, resulting in improved tunability and adaptability.

Further, due to the decoupling, a single stochastic unit (sMTJ 102) is able to drive multiple p-bits without being influenced by variations in the control signal, resulting in enhanced scalability of the modified p-bit structure 100B, simplifying its implementation in larger probabilistic computing systems. The modified p-bit structure 100B, as depicted in FIG. 1B, is suitable for applications requiring precise control over probabilistic behavior, such as optimization problems and probabilistic computing.

FIG. 2A(I) illustrates a diagram 200A depicting a stochastic magnetic tunnel junction (sMTJ) with its associated layers, along with the application of High Barrier Magnets (HBMs) 208 and Low Barrier Magnets (LBMs) 210 having different coercivities. The sMTJ is composed of multiple distinct layers, including a free layer 202, an insulator 204, and a fixed layer 206 (shown in (i)).

The free layer 202 is a ferromagnetic layer with a magnetic moment that can switch between states due to thermal noise. This switching ability gives the free layer 202 its stochastic behavior, which is utilized for probabilistic computing applications. The magnetic moment of the free layer 202 is not fixed and is influenced by thermal energy.

The insulator 204 is a thin, non-conductive layer that separates the free layer 202 from the fixed layer 206. The insulator 204 acts as a tunnel barrier, allowing electrons to pass through quantum tunnelling. The properties of the insulator 204 determine the resistance state of the sMTJ, depending on the relative alignment of the magnetic moments in the free layer 202 and fixed layer 206.

The fixed layer 206 is a ferromagnetic layer within the sMTJ having a stable and non-fluctuating magnetic moment. The fixed magnetic moment of the fixed layer 206 provides a reference point for the magnetic alignment of the free layer 202. Depending on whether the magnetic moments of the free layer 202 and the fixed layer 206 are aligned in parallel or anti-parallel, the sMTJ exhibits different resistance states.

FIG. 2A(II) further depicts the application of high barrier magnets (HBMs) and low barrier magnets (LBMs) in different technologies. In this illustration, HBMs 208 are utilized for magnetic random access memory (MRAM) applications, whereas LBMs 210 are employed for probabilistic bit (p-bit) applications.

High Barrier Magnets (HBMs) 208 are magnets with a significant energy barrier that maintain their magnetic state in a stable manner. The stability results in deterministic behavior, meaning that a state of the magnet does not easily change under normal conditions, which is essential for memory applications where data integrity and retention are important. In Magnetic Random Access Memory (MRAM), HBMs are used to store information reliably. MRAM is a non-volatile memory technology that uses magnetic states to represent binary data (0s and 1s). For example, the parallel magnetic alignment of HBMs corresponds to a low resistance state, representing a binary ‘0,’ while the anti-parallel alignment corresponds to a high resistance state, representing a binary ‘1.’ This deterministic switching allows MRAM to retain stored information without power, making it suitable for persistent memory storage in various computing devices.

Low Barrier Magnets (LBMs) 204, conversely, have a much lower energy barrier, allowing their magnetic state to fluctuate due to thermal noise even at room temperature. This makes LBMs stochastic in nature, meaning that their magnetic state can switch randomly between high and low resistance states without requiring external energy inputs. LBMs are used in probabilistic computing applications, such as p-bits, where randomness and probabilistic behavior are advantageous. P-bits are probabilistic bits that can fluctuate between states, unlike deterministic bits in classical computing. The stochastic behavior of LBMs 210 makes them well-suited for applications that involve stochastic processes, such as optimization problems, machine learning, and probabilistic logic. The ability to switch states randomly due to thermal energy allows LBMs to be used in artificial intelligence systems where the exploration of multiple possibilities is beneficial.

The HBMs 208, which provide stable magnetic states for memory retention, and the LBMs 210, which are inherently stochastic and are leveraged for their probabilistic switching capabilities are both needed to form a probabilistic bit generator. This differentiation is important for understanding their respective roles in modern computational technologies, where HBMs are used for reliable data storage and LBMs are used for generating randomness and enabling probabilistic computations. The sMTJ exhibits two resistance states: a low resistance state (P state 214, where magnetic moments are parallel) and a high resistance state (AP state 212, where magnetic moments are anti-parallel). For instance, the parallel alignment (P) 214 of the magnetic moments in the HBMs represents a low resistance state, which corresponds to a binary ‘0’, whereas the anti-parallel alignment (AP) 212 represents a high resistance state, corresponding to a binary ‘1’. The deterministic switching behavior permits the MRAM to retain data reliably without the need for continuous power. The stochastic switching between these resistance states is driven by thermal noise, making sMTJs suitable for probabilistic computing applications. The transient conductance of an MTJ is described by:

$${G}_{0} ( t ) = {G}_{0} [ 1 + {m}_{z} ( t ) \frac{TMR}{2 + TMR} ] \qquad ( 1 )$$

where G₀ is the average MTJ conductance, the magnetization M_{Z}(t) has the range of (−1, 1), where 1 is for the parallel (P) state and −1 for the anti-parallel (AP) state, and TMR is the tunnelling magnetoresistance, which is defined as:

$$TMR = ( {R}_{A P} - {R}_{P )} / {R}_{P} , \qquad ( 2 )$$

where R_{AP} is the anti-parallel resistance and R_{P} is the parallel resistance.

FIG. 2B illustrates a simulation environment 200B used to model the behavior of a stochastic magnetic tunnel junction (sMTJ) in a time-dependent manner. In the simulation environment, MATLAB 216 is used to generate the resistance states of the sMTJ as a function of time. These resistance states represent random fluctuations of the sMTJ between low and high resistance due to thermal effects at room temperature. MATLAB is a high-level programming environment utilized for numerical computation and data analysis. It generates a time series of resistance values that mimic the random behavior of an sMTJ. Each resistance value corresponds to a specific time index, representing how resistance of the sMTJ changes over time in response to thermal noise.

The generated resistance values are then used as inputs for LTSPICE 218, a widely used circuit simulation software (LTspice is a SPICE-based analog electronic circuit simulator computer software, produced by semiconductor manufacturer Analog Devices, One Analog Way Wilmington, MA 01887, United States of America). LTSPICE 218 is employed to model the sMTJ as a time-varying resistance element in an electronic circuit. By inputting the time-dependent resistance values from MATLAB 216, LTSPICE 218 simulates the impact of the stochastic switching on circuit performance, providing insights into how sMTJs can be integrated into practical electronic systems.

The combination of MATLAB 216 and LTSPICE 218 allows for a comprehensive simulation of behavior of the sMTJ in a circuit environment, predicting how stochastic devices can be used in real-world applications. For example, the fluctuating resistance of the sMTJ is used to generate random numbers, which are important for encryption and security applications.

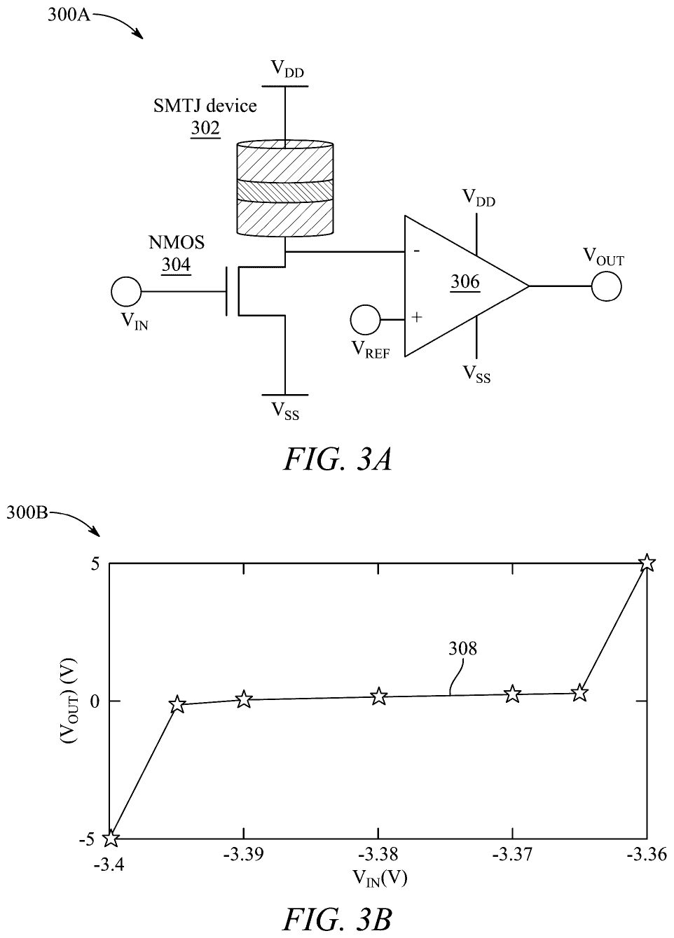

FIG. 3A illustrates a conventional 1T1M probabilistic bit (p-bit) implementation 300, representing a circuit including a stochastic magnetic tunnel junction (sMTJ) device 302, an NMOS transistor 304, and a comparator 306. In an exemplary embodiment of the 1T1M structure 300, the positive voltage supply V_{DD} and the negative voltage supply V_{SS} are each set to a magnitude of 5 volts, as depicted in FIG. 3A.

A drain terminal of the NMOS transistor 304 is connected to the sMTJ device 302, and the source terminal is connected to the negative voltage supply V_{SS}. The p-bit output is taken from the drain node of the NMOS transistor 304. The drain node is also connected to the comparator 306. The reference voltage V_{ref} is supplied to the non-inverting input of the comparator 306, and the voltage from the drain node of the NMOS transistor 304 is fed to the inverting input of the comparator.

The NMOS transistor 304 and the sMTJ device 302 together function to create a probabilistic bit, with the drain node of the NMOS transistor 304 serving as the output point where the stochastic resistance of the sMTJ device 302 is observed. The stochastic magnetic tunnel junction operates with a fixed resistance characteristic, such that the current across the sMTJ does not affect its state, thereby rendering it non-tunable. Such lack of tunability limits the control over the stochastic properties of the p-bit, thus reducing the versatility in applications that require dynamic adjustments to the stochastic behavior.

The positive supply voltage V_{DD} provides the required bias for the NMOS transistor 304, while the negative supply V_{SS} establishes a stable operating point for the circuit. The comparator 306 compares the voltage at the drain node of the NMOS transistor 304 with the reference voltage V_{ref}, thereby determining the output state of the p-bit. Providing the reference voltage V_{ref} to the non-inverting input of the comparator 306 effectively couples the reference voltage to the sMTJ device 302, rendering the output non-tunable.

In this conventional p-bit implementation, the non-tunable sMTJ device 302 restricts the ability to control the stochastic behavior of the p-bit. The drain node of the NMOS transistor 304 serves as the point of observation for the stochastic resistance of the sMTJ device 302, and the comparator 306 provides the output signal based on this observed value. The restricted stochastic response of the p-bit, characterized by two possible resistance states, R_{P} and R_{MP}, is illustrated in FIG. 3B.

FIG. 3B illustrates the response curve 308 of the p-bit structure, specifically depicting the relationship between the time-averaged output voltage (V_{OUT}) and the input voltage (V_{IN}) without a source resistance for a single bipolar MTJ. The graph 300B shows the characteristic response of a binary MTJ, which alternates between two distinct resistance states, the anti-parallel resistance state (R_{AP}) and the parallel resistance state (R_{P}). In this example, the Tunnel Magnetoresistance (TMR) ratio is assumed to be 70%, and the inverse of the conductance G₀⁻¹ is set at 9000Ω.

The response curve 308 demonstrates the limited stochastic range of the conventional p-bit design when using a binary MTJ, where the p-bit only oscillates between R_{AP} and R_{P} without intermediate states. Such restricted response makes the implementation less versatile for applications that demand finer control over the stochastic nature of the p-bit. Consequently, the MTJ-based circuit results in reduced tunability and constrained stochastic range, which impacts its overall performance in probabilistic computing environments.

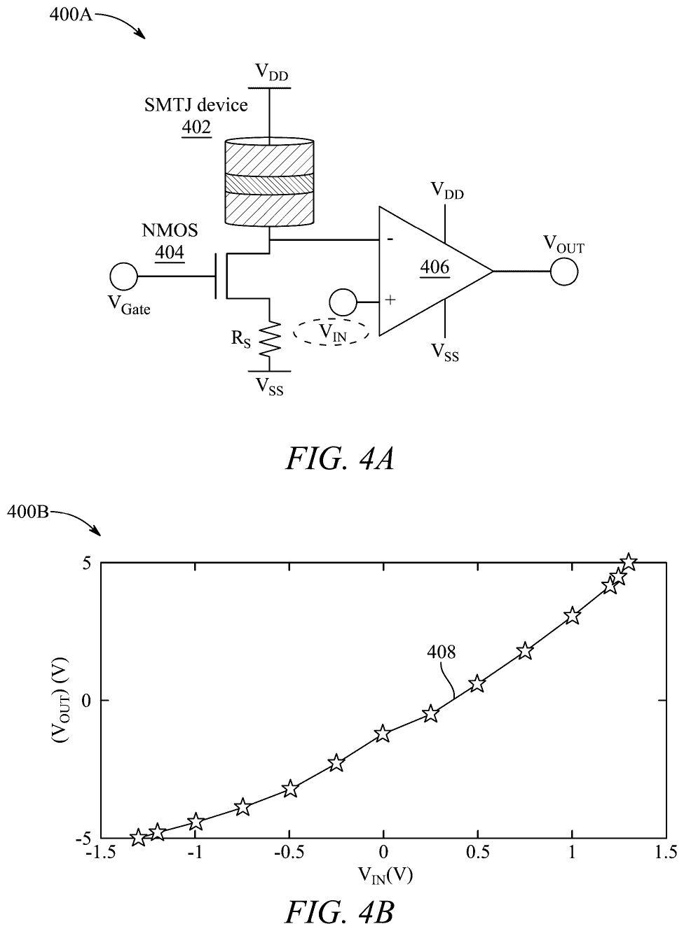

FIG. 4A illustrates a tunable decoupled probabilistic bit (p-bit) structure 400A of the present disclosure using a continuous sMTJ device 402. The tunable decoupled p-bit structure 400A is configured to decouple the stochastic path from the control path and to independent tune each path, thereby enhancing the stochastic behavior of the p-bit.

The tunable decoupled p-bit structure 400A includes an sMTJ device 402, an NMOS transistor 404, and a comparator 406. The sMTJ device 402 operates with fluctuating resistance states due to thermal noise, resulting in either a parallel (P) or anti-parallel (AP) state, determining the probabilistic nature of the p-bit.

In the tunable decoupled p-bit structure 400A, the gate terminal of the NMOS transistor 404 is maintained at a fixed voltage (V_{Gate}), while the input voltage is applied to the non-inverting terminal of the comparator 406. The source terminal of the NMOS transistor 404 is connected to a negative DC voltage supply (V_{SS}), and the drain terminal is connected to the sMTJ device 402. The drain voltage of the NMOS transistor 404 fluctuates between two fixed limits, which are determined by the gate voltage and the properties of the sMTJ device 402. The stochastic response from the drain node of the NMOS transistor 404 is then compared with the input voltage supplied to the comparator 406, thereby determining the p-bit output state at the comparator output.

The decoupling mechanism implemented in the present disclosure isolates the control input from the stochastic response of the sMTJ device 402. By fixing the gate voltage of the NMOS transistor 404, the stochastic path is independently tuned, so that the drain voltage fluctuates within two predetermined limits. These fluctuation limits are functions of the defined gate voltage and the characteristics of the sMTJ device 402. The input voltage applied to the comparator 406 scans the entire range of the voltage supply, from V_{SS} to a positive DC voltage supply, V_{DD}, to derive sigmoidal response of the p-bit.

In an implementation, the positive DC voltage supply (V_{DD}) and the negative DC voltage supply (V_{SS}) are each set at a magnitude of 5 volts, providing the required biasing conditions for the NMOS transistor 404 and the sMTJ device 402. The comparator 406 receives the input voltage at its non-inverting terminal and compares it to the fluctuating drain voltage of the NMOS transistor 404 at its inverting terminal, determining the probabilistic output state of the p-bit. The p-bit structure 400A achieves an extended stochastic range of approximately 25% of the voltage supply, providing significant improvement over conventional p-bit implementations.

FIG. 4B illustrates a simulation response curve 408 of a probabilistic bit (p-bit) structure 400A as implemented in the tunable decoupled architecture depicted in FIG. 4A. The graph 400B represents the time-averaged output of the p-bit in relation to the input voltage applied across the system. The stochastic range, indicated along the curve 408, quantifies the extent of voltage fluctuation that the p-bit output undergoes during operation, effectively capturing the range over which the system behaves stochastically.

The stochastic response curve 408 demonstrates that the tunable decoupling achieved in the design extends the stochastic range to approximately 25% of the voltage supply range. The curve 408 illustrates the improved dynamic range compared to traditional coupled designs, reflecting the influence of the fixed gate voltage and the input voltage applied to the comparator reference terminal. Tunnel Magnetoresistance (TMR) value used in this simulation is 70%, with an inverse conductance G₀⁽⁻¹⁾ of 9000Ω and a symmetric positive and negative voltage supply of V_{DD}=−V_{SS}=5V.

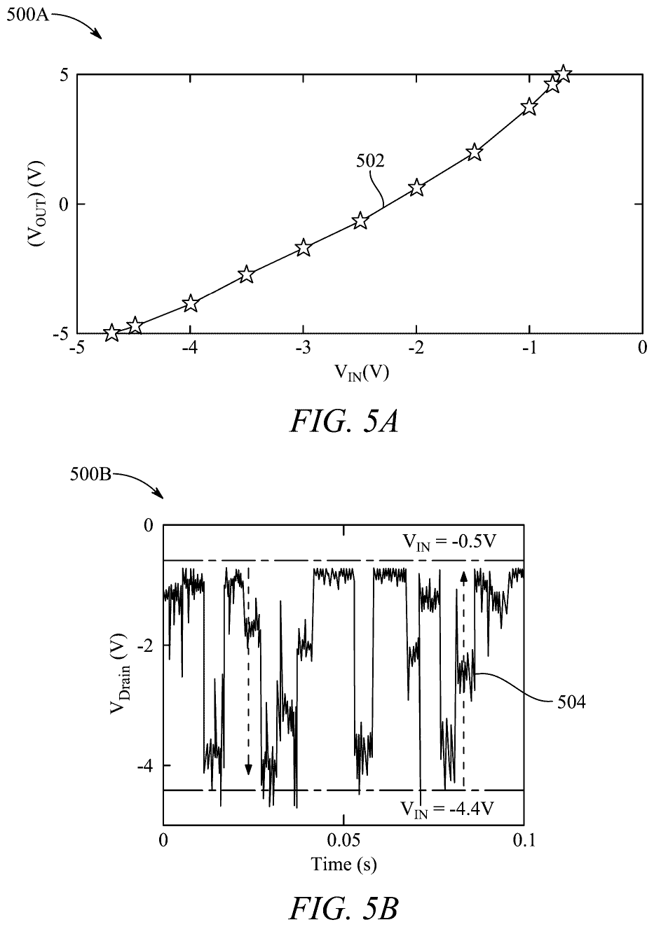

FIG. 5A illustrates a graph 500A providing the stochastic response curve 502 of the decoupled p-bit design, showing a significant increase in the stochastic range when compared to prior implementations. The stochastic range depicted in FIG. 5A is extended to approximately 50% of the voltage supply range, representing a substantial enhancement over the conventional design, which was limited by the coupling of stochastic and control paths. In the tunable decoupled p-bit structure 400A, the stochastic path is made independent of the input control path, thereby providing an enhanced stochastic response, as shown by the curve 502.

The curve 502 in FIG. 5A demonstrates the effectiveness of decoupling the stochastic path, which results in a broader fluctuation range for the output voltage. This increase in the stochastic range provides greater flexibility in probabilistic computations.

FIG. 5B illustrates a graph 500B indicating the fluctuation limits of the drain voltage for the tunable decoupled p-bit structure 400A, as represented by curve 504. The stochastic range in FIG. 5B is defined by the range of fluctuation at the drain node, which is determined by the two fixed limits between which the drain voltage oscillates. The curve 504 shows that the two limits of the stochastic range approximately coincide with the maximum and minimum values of the drain voltage fluctuations, further validating the extended stochastic range observed in the p-bit structure 400A.

The tunable decoupled configuration allows the drain voltage to vary between broader limits, thereby effectively doubling the stochastic range when compared to conventional designs. The broader stochastic range improves the output characteristics of the p-bit structures, making the p-bit structures more suitable for applications that require extensive probabilistic switching, such as optimization problems and artificial intelligence.

FIG. 5B illustrates the transient V_{Drain} as V_{IN} scans the whole range of values for V_{Drain}, where stochastic range is equivalent to the V_{Drain} range. TMR=70% and G₀⁻¹=9000Ω. The drain voltage and the input voltage (V_{Drain} ∝V_{IN}²), are described by:

$${V}_{Drain} = \frac{1}{2} {K}_{n} \frac{W}{L} {( {V}_{I N} − {V}_{S S} − {V}_{T} )}^{2} {R}_{Drain} \qquad ( 3 )$$

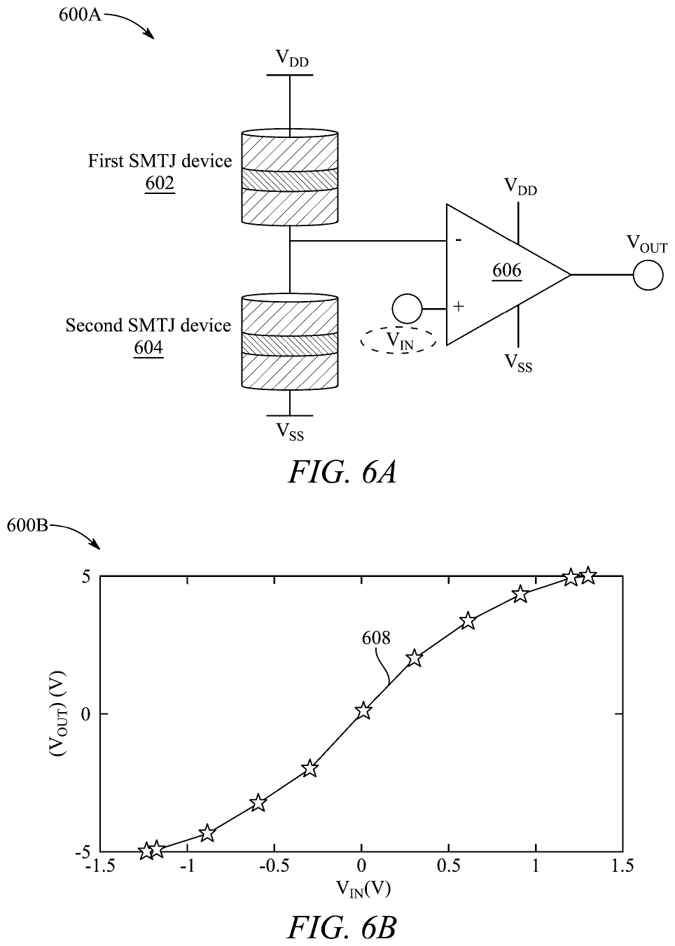

FIG. 6A illustrates a voltage divider 600A for a probabilistic bit (p-bit) including continuous Magnetic Tunnel Junctions (MTJs). The voltage divider 600 comprises a first stochastic magnetic tunnel junction device 602 and a second stochastic magnetic tunnel junction device 604. Each stochastic magnetic tunnel junction device, 602 and 604, consists of a first magnet and a second magnet, which are separated by an insulating layer. Electrical terminals are connected to each magnet to facilitate electrical connections for voltage application and signal generation.

The first electrical terminal of the first magnet in the first stochastic MTJ device 602 is connected to a positive DC voltage (V_{DD}), whereas the second electrical terminal of the second magnet in the second stochastic MTJ device 604 is connected to a negative DC voltage (V_{SS}), wherein the magnitude of V_{DD} equals −V_{SS}, with a value of 5V as depicted in FIG. 6A.

The comparator 606 is configured to compare the variable voltage V_{IN} to the voltage generated at the stochastic branch, which effectively shifts the probabilistic output signal of the p-bit at the non-inverting input to the comparator voltage output V_{OUT} when the probabilistic output signal of the p-bit is less than the variable input voltage V_{IN}. This decoupling mechanism provides the significant advantage of isolating the control input from the stochastic response, thus allowing a more precise adjustment of the stochastic properties of the p-bit without affecting the variable input voltage V_{IN}.

Each stochastic magnetic tunnel junction device, 602 and 604, is configured to generate probabilistic bits at a p-bit output terminal, which comprises the second electrical terminal of the first stochastic MTJ device and the first electrical terminal of the second stochastic MTJ device. These p-bits randomly oscillate between a first resistance state (R_{P}) and a second resistance state (R_{AP}) in response to thermal noise.

The comparator 606 includes a non-inverting input terminal, an inverting input terminal, a source terminal and a voltage output terminal. The inverting input terminal of the comparator 606 is connected to the p-bit output terminal, thus receiving the fluctuating voltage generated by each of the MTJ devices, 602 and 604. The non-inverting input terminal of the comparator 606 is connected to the variable input voltage (V_{IN}), providing a reference against which the MTJ output voltage is compared.

The output voltage V_{OUT} is given by:

$${V}_{OUT} = ( {V}_{D D} \cdot {R}_{MTJB} + {V}_{SS} \cdot {R}_{MTJT} ) / ( {R}_{MTJB +} {R}_{MTJT} ) \qquad ( 4 )$$

where R_{MTJB} is the resistance of the first stochastic MTJ device 602, and R_{MTJT} is the resistance of the second stochastic MTJ device 604. The voltage divider 600 thus generates an output voltage that reflects the stochastic response of the MTJ devices while being influenced by both the positive voltage V_{DD} and the negative voltage V_{SS}.

The tunnelling magnetoresistance (TMR) of each stochastic magnetic tunnel junction device, 602 and 604, is directly influenced by the ambient temperature of the surrounding environment. The thermal noise present at the ambient temperature causes the MTJ devices to fluctuate between the parallel resistance state R_{P} and the anti-parallel resistance state R_{AP}, thereby generating p-bits in response to this inherent thermal activity. The temperature dependence implies that the TMR value is directly related to the operational temperature, which affects the stochastic behavior and the reliability of the generated p-bits. The TMR of each of the first stochastic magnetic tunnel junction device and the second stochastic magnetic tunnel junction device is given by:

$$TMR = ( {R}_{A P} - {R}_{P} ) / {R}_{P} .$$

The stochastic range (S_{range}) of the p-bits at the output terminal is a function of the TMR of each stochastic magnetic tunnel junction device and is proportional to the voltage difference between the positive DC voltage V_{DD} and the negative DC voltage V_{SS}. Specifically, the stochastic range of the p-bit output is extended when the TMR increases. The relationship between TMR and stochastic range is expressed by the following equation:

$${V}_{Srange} = ( ( {V}_{D D} - {V}_{SS} ) \cdot TMR ) / ( 2 + T M R ) \qquad ( 5 )$$

The stochastic range is enhanced by employing two MTJ devices, 602 and 604, at the stochastic branch, thus allowing flexibility in determining the output voltage V_{OUT}.

Each of the first and second stochastic MTJ devices 602 and 604 is capable of generating p-bits having a parallel resistance state (R_{P}) and an anti-parallel resistance state (R_{AP}). The TMR of each of the first stochastic magnetic tunnel junction device and the second stochastic magnetic tunnel junction device is given by:

$$TMR = ( {R}_{A P} - {R}_{P} ) / {R}_{P}$$

The equation represents the ratio between the resistance states, where the TMR value dictates the fluctuation characteristics of the MTJ device. The resistance states, R_{P} and R_{AP}, play an essential role in determining the stochastic range and thus the behavior of the p-bit output.

The variable voltage V_{IN} serves as a tuneable comparator reference voltage, which can be swept to obtain the p-bit output in response to the input voltage. Each stochastic MTJ device, 602 and 604, may also be configured as a superparamagnetic tunnel junction device. Each of the first stochastic magnetic tunnel junction device and the second stochastic magnetic tunnel junction device are superparamagnetic tunnel junction devices configured to have a p-bit response m at the second electrical terminal of the first stochastic magnetic tunnel junction device given by:

$$m = sgn [ tanh ( β V ) - {r}_{U} ] \qquad ( 6 )$$

where sgn represents the sign function, V is the voltage at the inverting terminal of the comparator, β is a beta factor related to the temperature inverse, and r_{U} is a uniform random variable ranging from −1 to 1. A uniform random variable is one in which all outcomes are equally likely.

The beta factor β is crucial in defining the influence of temperature on the p-bit response and is given by:

$$β = 2 ( TMR + 2 ) ( arc tanh ( 0.99 ) / TMR ( {V}_{D D} - {V}_{SS} ) ) \qquad ( 7 )$$

The beta factor dictates the stochastic response, which influences the degree of randomness in the output signal of the p-bit.

FIG. 6B is a graph 600B that indicates the corresponding p-bit response curve 608 of the voltage divider 600, as depicted in FIG. 6A, showing the relationship between the time-averaged output voltage (V_{OUT}) and the input voltage (V_{IN}). The stochastic response in FIG. 6B is achieved with a Tunnel Magnetoresistance (TMR) ratio of 70% and an inverse conductance G₀⁻¹ of 9000Ω. The curve 608 demonstrates that the voltage divider 600 extends the stochastic range of the p-bit.

The response curve 608 indicates that the stochastic range of the p-bit in the decoupled design is approximately 25% to 35% of the voltage supply range. This significant improvement is achieved by implementing g two MTJs 602 and 604 at the stochastic branch, which together form a voltage divider, thereby increasing the flexibility in determining the output voltage V_{OUT}.

FIG. 6B provides a visual representation of the stochastic response achieved by the decoupled design. The p-bit response curve 608 illustrates how the time-averaged output voltage (V_{OUT}) varies as a function of the input voltage (V_{IN}). The response curve 608 demonstrates the probabilistic nature of the output, which fluctuates between two distinct resistance states, RAP and RP, in response to the thermal noise inherent in the MTJ devices. The curve reflects the stochastic behavior achieved through the use of two identical MTJ devices, where the stochastic range is proportional to the TMR value and extends across a significant portion of the voltage supply range (V_{DD} to V_{SS}).

The response shown in FIG. 6B highlights the scalability and tunability of the proposed design, as it allows for a more extensive stochastic range compared to conventional single-MTJ designs. By employing a voltage divider configuration with two MTJs, the proposed design ensures that the output signal V_{OUT} is influenced by both MTJ devices, resulting in a smoother and more continuous probabilistic response. The response curve 608 further validates that the stochastic range achieved is approximately 25% of the total voltage supply, which can be further increased by optimizing the TMR ratio of the MTJs.

FIG. 6C illustrates a random number generator 600C comprising a stochastic device 610, a control unit 612, and an activation unit 614. The stochastic device 610 is configured with a first electrical terminal, a second electrical terminal, and a probabilistic bit (p-bit) output terminal. Each stochastic device 610 is designed to generate p-bits at the p-bit output terminal, where the p-bits randomly oscillate between a parallel resistance state (R_{P}) and an anti-parallel resistance state (R_{AP}) in response to thermal noise.

The random number generator 600 utilizes a positive DC voltage (V_{DD}) that is connected to the first electrical terminal of the stochastic device 610, and a negative DC voltage (V_{SS}) that is connected to the second electrical terminal of the stochastic device 610. The positive and negative voltage supplies (V_{DD} and V_{SS}) provide the necessary electrical bias for the stochastic device 610 to operate in a manner that allows its magnetic state to fluctuate due to inherent thermal noise.

The stochastic device 610 is preferably an electrically connected pair of magnetic tunnel junction (MTJ) devices. In this configuration, the positive DC voltage V_{DD} is connected to a first MTJ device, and the negative DC voltage V_{SS} is connected to a second MTJ device. The p-bit output terminal is connected to a node that interconnects the first MTJ device with the second MTJ device, thereby establishing a voltage divider configuration for generating a probabilistic output voltage V_{OUT}. This output voltage is given by:

$${V}_{out} = ( {V}_{D D} \cdot {R}_{MTJB} + {V}_{SS} \cdot {R}_{MTJT} ) / ( {R}_{MTJB +} {R}_{MTJT} )$$

where R_{MTJB} represents the resistance of the first MTJ device and R_{MTJT} represents the resistance of the second MTJ device. The resultant voltage V_{OUT} at the output terminal is indicative of the p-bit state generated by the stochastic device 610.

The activation unit 614 is an essential component of the random number generator 600. It includes a first input terminal, a second input terminal, and an activation unit output terminal. The first input terminal of the activation unit 614 is connected to the p-bit output terminal of the stochastic device 610, thereby receiving the fluctuating voltage generated by the stochastic unit. The second input terminal is connected to the control unit 612, which provides an input signal for activation. The activation unit 614 is configured to generate a voltage output signal Vₒᵤₜ based on the resistance state of each p-bit upon receiving an input signal from the control unit 612.

The control unit 612 is configured to generate a variable input voltage V_{IN}, which is utilized to influence the activation unit 614. The activation unit 614 may be implemented as a comparator, wherein the inverting input terminal is connected to the p-bit output terminal and the non-inverting input terminal is connected to the control unit 612. The comparator includes a source terminal, a drain terminal, and a voltage output terminal, where the drain terminal is connected to the positive DC voltage V_{DD}, and the source terminal is connected to the negative DC voltage V_{SS}.

The tunnelling magnetoresistance (TMR) of each MTJ device is directly related to the ambient temperature of the surrounding environment. This relationship is significant for the operation of the stochastic device 610. Each MTJ device in the stochastic device 610 is configured to generate p-bits in response to thermal noise present at the ambient temperature. The TMR is given by:

$$TMR = ( {R}_{A P} - {R}_{P} ) / {R}_{P}$$

where R_{AP} represents the resistance in the anti-parallel state, and R_{P} represents the resistance in the parallel state. The thermal noise influences the transition between these resistance states, leading to a stochastic output.

Each superparamagnetic tunnel junction (sMTJ) device is characterized by a tunneling magnetoresistance (TMR), which is inherently dependent on the ambient temperature of the surrounding environment. The TMR is influenced by the thermal energy available in the environment, which directly affects the magnetic states of the sMTJ device. The ambient temperature plays a crucial role in defining the probability of switching between different magnetic states, thereby determining the tunneling resistance exhibited by the device.

In a superparamagnetic state, the magnetic moments of the tunnel junction are not fixed and fluctuates due to thermal agitation. Due to this phenomenon, the TMR is highly responsive to changes in the surrounding temperature. As the temperature increases, the thermal energy available to the magnetic moments also increases, which results in more frequent transitions between the parallel resistance state (R_{P}) and the anti-parallel resistance state (R_{AP}). The ratio of these resistance states is denoted by the TMR and is given by:

$$TMR = ( {R}_{A P} - {R}_{P} ) / {R}_{P}$$

where R_{AP} is the resistance of the sMTJ device when the magnetic layers are aligned in an anti-parallel manner, and R_{P} is the resistance when they are aligned in parallel. The value of TMR is thus indicative of the sensitivity of the sMTJ device to changes in thermal conditions, and it determines the extent of resistance variation that can be achieved.

The stochastic range (S_{range}) of the p-bits at the output terminal is a function of the TMR of each MTJ device and is proportional to the voltage difference between the positive DC voltage V_{DD} and the negative DC voltage V_{SS}. The stochastic range V_{Srange} at the output voltage Vₒᵤₜ is expressed as:

$${V}_{Srange} = ( ( {V}_{DD} - {V}_{SS} ) \cdot TMR ) / ( 2 + TMR )$$

This equation defines the proportional relationship between the stochastic range and the TMR, which can be manipulated by adjusting the voltage supplies V_{DD} and V_{SS}.

The p-bit response (m) at the output terminal of the stochastic device 610 can be mathematically expressed as:

$$m = sgn [ tanh ( β V ) - {r}_{U} ]$$

where sgn is the sign function, V is the voltage at the inverting terminal of the comparator, β is a beta factor related to the temperature inverse, and r_{U} is a uniform random variable ranging from −1 to 1.

The beta factor is defined as:

$$β = 2 ( TMR + 2 ) \cdot ( arc tanh ( 0.99 ) / ( TMR \cdot ( {V}_{D D} - {V}_{S S} ) )$$

The beta factor directly influences the stochastic behavior of the p-bit, as it determines the degree to which thermal noise affects the probabilistic state transitions between the parallel and anti-parallel resistance states.

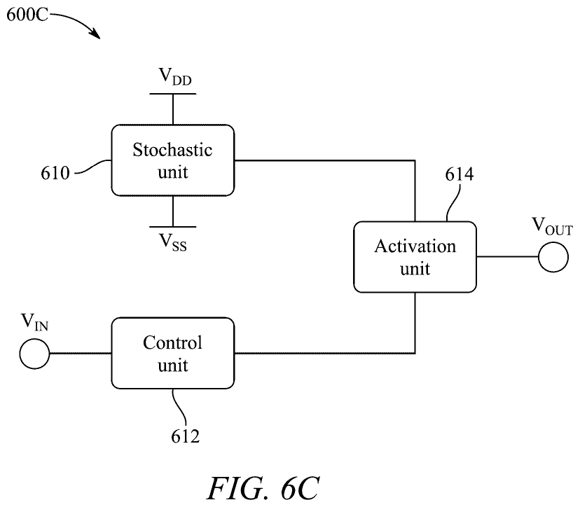

FIG. 7 illustrates a graph 700 depicting an analytical limit for the voltage divider decoupled design employing stochastic magnetic tunnel junctions (MTJs), where an increased stochastic range is achievable at higher Tunnel Magnetoresistance (TMR) values. The plot shows a stochastic range curve 702, representing the proportion of the voltage supply that is utilized for stochastic fluctuations as a function of TMR values for the two MTJ devices forming the voltage divider.

The stochastic range curve 702 depicts theoretically the manner in which, as the TMR value of the MTJs increases, the stochastic range of the p-bit proportionally expands, reaching significant portions of the entire voltage supply. This trend is shown in the context of multiple experimental implementations of p-bits 704, 706, 708, and 710, which were reported in literature, each falling below the theoretical limit. Specifically, the plot includes experimental data points corresponding the literature which showcase p-bit implementations with varying stochastic ranges achieved at different TMR ratios, (See: (702) Kobayashi, Keito, et al. “CMOS+ stochastic nanomagnets: heterogeneous computers for probabilistic inference and learning”, arXiv preprint arXiv:2304.05949 (2023); (704) Kaiser, Jan, et al. “Hardware-aware in situ learning based on stochastic magnetic tunnel junctions”, Physical Review Applied 17.1 (2022); (706) Grimaldi, Andrea, et al. “Experimental evaluation of simulated quantum annealing with MTJ-augmented p-bits.” 2022 International Electron Devices Meeting (IEDM). IEEE, 2022; (708) Borders, William A., et al. “Integer factorization using stochastic magnetic tunnel junctions.” Nature 573.7774 (2019): 390-393, each incorporated herein by reference in its entirety).

The graph 700 illustrates that the practical realizations of p-bit devices, while varying in performance, are generally constrained below the ideal limit for stochastic range expansion, as depicted by the stochastic range curve 702.

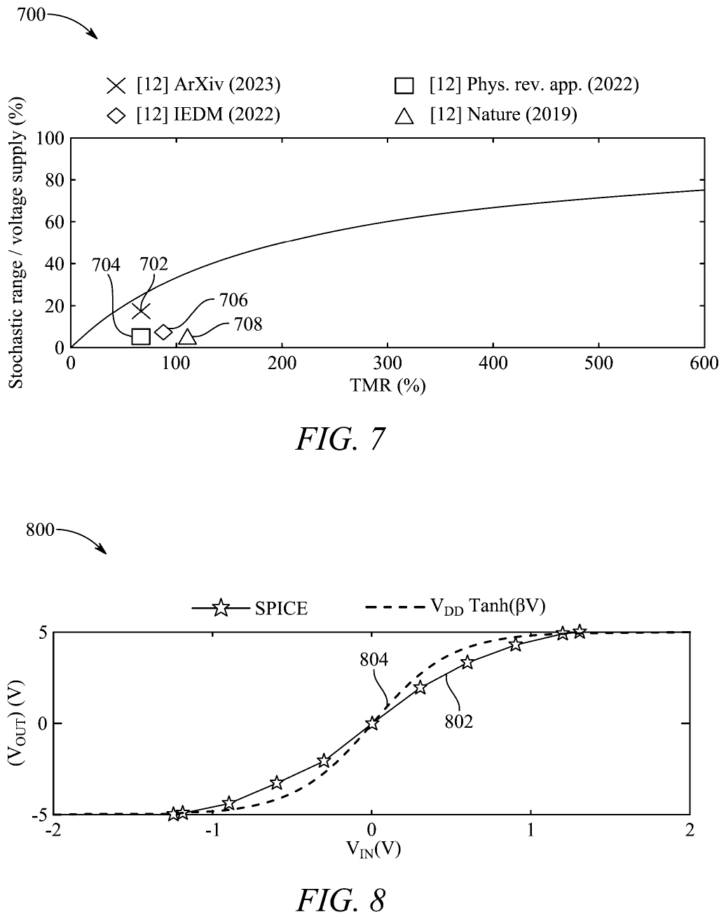

FIG. 8 illustrates a comparative mapping 800 of the average stochastic response of the voltage divider implementation of a p-bit (derived from simulation) to the hyperbolic tangent function (tan h). The response curve 802 obtained from the SPICE simulation of the proposed voltage divider design was mapped to the tan h function 804, scaled by the positive DC voltage (V_{DD}) for an appropriate match between the limits of both curves.

In particular, the SPICE simulation response curve 802 shows the average voltage output (V_{OUT}) as a function of the input voltage (V_{IN}), demonstrating the stochastic characteristics of the p-bit under the influence of thermal noise and MTJ switching. The tan h function 804, on the other hand, represents the theoretical response of the p-bit in an Ising machine configuration, wherein the probabilistic output (m) converges to the Boltzmann distribution as described by equation (6) in the disclosure.

The requirement for scaling by V_{DD} arises from the fact that the tan h function has an intrinsic output range between −1 and 1, whereas the output voltage range for the proposed voltage divider design spans from negative V_{DD} to positive V_{DD}, given that V_{DD}=−V_{SS}. The mapping between the SPICE simulation response curve 802 and the tan h function curve 804 validates the effectiveness of the proposed decoupled voltage divider design in emulating a stochastic response, thereby making it suitable for use in probabilistic computing applications such as Ising machines.

Various embodiments are illustrated by FIG. 1A to FIG. 8. In a first embodiment a voltage divider is described, comprising a first stochastic magnetic tunnel junction device and a second stochastic magnetic tunnel junction device, wherein each stochastic magnetic tunnel junction device includes a first magnet and a second magnet, wherein the first magnet and the second magnet are separated by an insulator, a first electrical terminal connected to the first magnet and a second electrical terminal connected to the second magnet, wherein each stochastic magnetic tunnel junction device is configured to generate probabilistic bits (p-bits) at a p-bit output terminal comprising the second electrical terminal of the first stochastic magnetic tunnel junction device and the first electrical terminal of the second stochastic magnetic tunnel junction device, wherein the p-bits randomly oscillate between a first resistance state and a second resistance state in response to thermal noise. The voltage divider comprises a positive DC voltage V_{DD} connected to the first electrical terminal of the first stochastic magnetic tunnel junction device and a negative DC voltage V_{SS} connected to the second electrical terminal of the second stochastic magnetic tunnel junction device. The voltage divider includes a comparator including a non-inverting input terminal, an inverting input terminal and a voltage output terminal, wherein the inverting terminal is connected to the p-bit output terminal and the non-inverting terminal is connected to a variable voltage V_{IN}, a terminal connected to the positive DC voltage V_{DD} and a terminal to the negative DC voltage V_{SS}, where a voltage Vₒᵤₜ at the voltage output terminal is given by:

$${V}_{out} = ( {V}_{D D} \cdot {R}_{MTJB} + {V}_{SS} \cdot {R}_{MTJT} ) / ( {R}_{MTJB +} {R}_{MTJT} ) ,$$

where R_{MTJB} is a resistance of the first stochastic magnetic tunnel junction device and R_{MTJT} is a resistance of the second stochastic magnetic tunnel junction device.

In one aspect, a tunnelling magnetoresistance (TMR) of each stochastic magnetic tunnel junction device is directly related to an ambient temperature of an environment surrounding the stochastic magnetic tunnel junction device, wherein each stochastic magnetic tunnel junction device is configured to generate p-bits in response to the thermal noise at the ambient temperature.

In one aspect, a stochastic range (S_{range}) of the p-bits at the output terminal is a function of the TMR of each stochastic magnetic tunnel junction device and is proportional to a voltage difference between the positive DC voltage V_{DD} and the negative DC voltage V_{SS}.

In one aspect, each of the first stochastic magnetic tunnel junction device and the second stochastic magnetic tunnel junction device is configured to generate p-bits having a parallel resistance state R_{P} and an anti-parallel resistance state R_{AP}, wherein the TMR of each of the first stochastic magnetic tunnel junction device and the second stochastic magnetic tunnel junction device is given by:

$$TMR = ( {R}_{A P} - {R}_{P} ) / {R}_{P} .$$

In one aspect, the stochastic range V_{Srange} of the voltage divider is given by:

$${V}_{Srange} = ( ( {V}_{D D} - {V}_{SS} ) \cdot TMR ) / ( 2 + TMR ) .$$

In one aspect, the variable voltage V_{IN} is configured to be a tunable comparator reference voltage.

In one aspect, each of the first stochastic magnetic tunnel junction device and the second stochastic magnetic tunnel junction device are superparamagnetic tunnel junction devices configured to have a p-bit response m at the second electrical terminal of the first stochastic magnetic tunnel junction device given by:

$$m = sgn [ tanh ( β V ) - {r}_{U} ] ,$$

where sgn is a sign function, V is a voltage at the inverting terminal of the comparator, β is a beta factor related to a temperature inverse and r_{U} is a uniform random variable that ranges from −1 to 1.

In one aspect, each of the superparamagnetic tunnel junction devices is configured to generate p-bits having a parallel resistance state R_{P} and an anti-parallel resistance state R_{AP}, wherein a tunneling magnetoresistance TMR of each of the first stochastic magnetic tunnel junction device and the second stochastic magnetic tunnel junction device is given by:

$$TMR = ( {R}_{A P} - {R}_{P} ) / {R}_{P} .$$

In one aspect, the beta factor β is given by:

$$β = 2 ( TMR + 2 ) ( arc tanh ( 0.99 ) / ( TMR ( {V}_{D D} - {V}_{S S} ) ) .$$

In one aspect, a stochastic range ((V_{Srange}) of the p-bits at the output terminal is a function of the TMR of each superparamagnetic tunnel junction device and is proportional to a voltage difference between the positive DC voltage V_{DD} and the negative DC voltage V_{SS}.

In a second embodiment, a random number generator is described which comprises a stochastic device configured with a first electrical terminal, a second electrical terminal and a probabilistic bit (p-bit) output terminal, wherein each stochastic device is configured to generate p-bits at the p-bit output terminal which randomly oscillate between a parallel resistance state R_{P} and an anti-parallel resistance state R_{AP} in response to thermal noise. The random number generator includes a positive DC voltage V_{DD} connected to the first electrical terminal of the stochastic device and a negative DC voltage V_{SS} connected to the second electrical terminal of the stochastic device.

The random number generator includes an activation unit including a first input terminal, a second input terminal, an activation unit output terminal, wherein the first input terminal is connected to the p-bit output terminal and the second input terminal is connected to a control unit, wherein the activation unit is configured to generate a voltage output signal Vₒᵤₜ based on the resistance state of each p-bit upon receiving an input signal from the control unit.

In one aspect, the stochastic device is an electrically connected pair of magnetic tunnel junction devices, wherein the positive DC voltage V_{DD} is connected to a first magnetic tunnel junction device, a negative DC voltage V_{SS} is connected to a second magnetic tunnel junction, and the first input terminal is connected to a terminal connecting the first magnetic tunnel junction device with the second magnetic tunnel junction device.

A voltage Vₒᵤₜ at the voltage output terminal is given by:

$${V}_{out} = ( {V}_{D D} \cdot {R}_{MTJB} + {V}_{SS} \cdot {R}_{MTJT} ) / ( {R}_{MTJB +} {R}_{MTJT} ) ,$$

where R_{MTJB} is a resistance of the first stochastic magnetic tunnel junction device and R_{MTJT} is a resistance of the second stochastic magnetic tunnel junction device.

In one aspect, a tunnelling magnetoresistance (TMR) of each magnetic tunnel junction device is directly related to an ambient temperature of an environment surrounding the magnetic tunnel junction device, wherein each magnetic tunnel junction device is configured to generate the p-bits in response to the thermal noise at the ambient temperature.

In one aspect, the TMR of each of the first magnetic tunnel junction device and the second magnetic tunnel junction device is given by:

$$TMR = ( {R}_{A P} - {R}_{P} ) / {R}_{P} .$$

In one aspect, a stochastic range (V_{Srange}) of the p-bits at the output terminal is a function of the TMR of each magnetic tunnel junction device and is proportional to a voltage difference between the positive DC voltage V_{DD} and the negative DC voltage V_{SS}.

In one aspect, V_{Srange} at the voltage output Vₒᵤₜ is given by:

$${V}_{Srange} = ( ( {V}_{D D} - {V}_{SS} ) \cdot TMR ) / ( 2 + TMR )$$

In one aspect, the activation unit is a comparator including a non-inverting input terminal, an inverting input terminal, a source terminal, a drain terminal and a voltage output terminal. The inverting input terminal is connected to the p-bit output terminal, the non-inverting input terminal is connected to the control unit, wherein the control unit is configured to generate a variable voltage V_{IN}.

In one aspect, the stochastic device is an electrically connected pair of superparamagnetic tunnel junction devices configured to have a p-bit response m at the p-bit output terminal given by:

$$m = sgn [ tanh ( β V ) - {r}_{U} ] ,$$

where sgn is a sign function, V is a voltage at the inverting terminal of the comparator, β is a beta factor related to a temperature inverse, and r_{U} is a uniform random variable that ranges from −1 to 1.

In one aspect, a tunnelling magnetoresistance (TMR) of each superparamagnetic tunnel junction device is directly related to an ambient temperature of an environment surrounding the superparamagnetic tunnel junction device, wherein each superparamagnetic tunnel junction device is configured to generate the p-bits in response to the thermal noise at the ambient temperature,

wherein the TMR of each superparamagnetic tunnel junction device is given by:

$$TMR = ( {R}_{A P} - {R}_{P} ) / {R}_{P} ,$$

and
wherein the beta factor β is given by:

$$β = 2 ( T M R + 2 ) ( arctanh ( 0.99 ) / T M R \cdot ( {V}_{DD} - {V}_{SS} ) ) .$$

In a third embodiment, a method is described of implementing a tunable probabilistic bit (p-bit) voltage divider comprising connecting a first stochastic magnetic tunnel junction device to a second stochastic magnetic tunnel junction device, connecting a positive DC voltage V_{DD} to the first electrical terminal of the first stochastic magnetic tunnel junction device, and connecting a negative DC voltage V_{SS} connected to the second electrical terminal of the second stochastic magnetic tunnel junction device, wherein each stochastic magnetic tunnel junction device is configured to generate p-bits which randomly oscillate between a first resistance state and a second resistance state in response to thermal noise. The method includes generating, at a p-bit output terminal comprising the second electrical terminal of the first stochastic magnetic tunnel junction device and the first electrical terminal of the second stochastic magnetic tunnel junction device, p-bit output signals, connecting an inverting terminal of a comparator to the p-bit output terminal, connecting a non-inverting terminal of the comparator to a variable voltage V_{IN}, and connecting a terminal to the positive DC voltage V_{DD}. The method further includes connecting a terminal to the negative DC voltage V_{SS}, increasing a voltage of the variable voltage V_{IN} until the variable voltage V_{IN} is equal to a voltage received at the inverting terminal based on the p-bit output signals, and generating a voltage Vₒᵤₜ at the voltage output terminal given by:

$${V}_{out} = ( {V}_{DD} \cdot {R}_{MTJB} + {V}_{SS} \cdot {R}_{MTJT} ) / ( {R}_{MTJB +} {R}_{MTJT} ) ,$$

where R_{MTJB} is a resistance of the first stochastic magnetic tunnel junction device, and R_{MTJT} is the resistance of the second stochastic magnetic tunnel junction device.

The above-described hardware description is a non-limiting example of corresponding structure for performing the functionality described herein.

Numerous modifications and variations of the present disclosure are possible in light of the above teachings. It is therefore to be understood that within the scope of the appended claims, the invention may be practiced otherwise than as specifically described herein.

1. A voltage divider, comprising:
a first stochastic magnetic tunnel junction device and a second stochastic magnetic tunnel junction device, wherein each stochastic magnetic tunnel junction device includes a first magnet and a second magnet, wherein the first magnet and the second magnet are separated by an insulator, a first electrical terminal connected to the first magnet and a second electrical terminal connected to the second magnet, wherein each stochastic magnetic tunnel junction device is configured to generate probabilistic bits (p-bits) at a p-bit output terminal comprising the second electrical terminal of the first stochastic magnetic tunnel junction device and the first electrical terminal of the second stochastic magnetic tunnel junction device, wherein the p-bits randomly oscillate between a first resistance state and a second resistance state in response to thermal noise;
a positive DC voltage V_{DD} connected to the first electrical terminal of the first stochastic magnetic tunnel junction device;
a negative DC voltage V_{SS} connected to the second electrical terminal of the second stochastic magnetic tunnel junction device; and
a comparator including a non-inverting input terminal, an inverting input terminal, a source terminal, and a voltage output terminal, wherein the inverting terminal is connected to the p-bit output terminal, the non-inverting terminal is connected to a variable voltage V_{IN}, and wherein a voltage Vₒᵤₜ at the voltage output terminal is given by:
$${V}_{out} = ( {V}_{DD} \cdot {R}_{MTJB} + {V}_{SS} \cdot {R}_{MTJT} ) / ( {R}_{MTJB +} {R}_{MTJT} ) ,$$
where R_{MTJB} is a resistance of the first stochastic magnetic tunnel junction device and R_{MTJT} is a resistance of the second stochastic magnetic tunnel junction device.

2. The voltage divider of claim 1, wherein a tunnelling magnetoresistance (TMR) of each stochastic magnetic tunnel junction device is directly related to an ambient temperature of an environment surrounding the stochastic magnetic tunnel junction device, wherein each stochastic magnetic tunnel junction device is configured to generate p-bits in response to the thermal noise at the ambient temperature.

3. The voltage divider of claim 2, wherein a stochastic range (S_{range}) of the p-bits at the output terminal is a function of the TMR of each stochastic magnetic tunnel junction device and is proportional to a voltage difference between the positive DC voltage V_{DD} and the negative DC voltage V_{SS}.

4. The voltage divider of claim 3, wherein each of the first stochastic magnetic tunnel junction device and the second stochastic magnetic tunnel junction device is configured to generate p-bits having a parallel resistance state R_{P} and an anti-parallel resistance state R_{AP}, wherein the TMR of each of the first stochastic magnetic tunnel junction device and the second stochastic magnetic tunnel junction device is given by:
$$T M R = ( {R}_{AP} - {R}_{P} ) / {R}_{P} .$$

5. The voltage divider of claim 4, wherein the stochastic range V_{Srange} of the voltage divider is given by:
$${V}_{Strange} = ( ( {V}_{DD} - {V}_{SS} ) \cdot T M R ) / ( 2 + T M R ) .$$

6. The voltage divider of claim 1, wherein the variable voltage V_{IN} is configured to be a tunable comparator reference voltage.

7. The voltage divider of claim 1, wherein each of the first stochastic magnetic tunnel junction device and the second stochastic magnetic tunnel junction device are superparamagnetic tunnel junction devices configured to have a p-bit response m at the second electrical terminal of the first stochastic magnetic tunnel junction device given by:
$$m = sgn [ tanh ( β V ) - {r}_{U} ] ,$$
where sgn is a sign function, V is a voltage at the inverting terminal of the comparator, β is a beta factor related to a temperature inverse and r_{U} is a uniform random variable that ranges from −1 to 1.

8. The voltage divider of claim 7, wherein each of the superparamagnetic tunnel junction devices is configured to generate p-bits having a parallel resistance state R_{P} and an anti-parallel resistance state R_{AP}, wherein a tunneling magnetoresistance TMR of each of the first stochastic magnetic tunnel junction device and the second stochastic magnetic tunnel junction device is given by:
$$T M R = ( {R}_{AP} - {R}_{P} ) / {R}_{P} .$$

9. The voltage divider of claim 8, wherein the beta factor β is given by:
$$β = 2 ( T M R + 2 ) ( arctanh ( 0.99 ) / ( T M R ( {V}_{DD} - {V}_{SS} ) ) .$$

10. The voltage divider of claim 7, wherein a stochastic range ((V_{Srange}) of the p-bits at the output terminal is a function of the TMR of each superparamagnetic tunnel junction device and is proportional to a voltage difference between the positive DC voltage V_{DD} and the negative DC voltage V_{SS}.

11. A random number generator, comprising:
a stochastic device configured with a first electrical terminal, a second electrical terminal and a probabilistic bit (p-bit) output terminal, wherein each stochastic device is configured to generate p-bits at the p-bit output terminal which randomly oscillate between a parallel resistance state R_{P} and an anti-parallel resistance state R_{AP} in response to thermal noise;
a positive DC voltage V_{DD} connected to the first electrical terminal of the stochastic device;
a negative DC voltage V_{SS} connected to the second electrical terminal of the stochastic device; and
an activation unit including a first input terminal, a second input terminal, an activation unit output terminal, wherein the first input terminal is connected to the p-bit output terminal and the second input terminal is connected to a control unit, wherein the activation unit is configured to generate a voltage output signal Vₒᵤₜ based on the resistance state of each p-bit upon receiving an input signal from the control unit.

12. The random number generator of claim 11, wherein the stochastic device is an electrically connected pair of magnetic tunnel junction devices, wherein the positive DC voltage V_{DD} is connected to a first magnetic tunnel junction device;
a negative DC voltage V_{SS} is connected to a second magnetic tunnel junction;
the first input terminal is connected to a terminal connecting the first magnetic tunnel junction device with the second magnetic tunnel junction device; and
a voltage Vₒᵤₜ at the voltage output terminal is given by:
$${V}_{out} = ( {V}_{DD} \cdot {R}_{MTJB} + {V}_{SS} \cdot {R}_{MTJT} ) / ( {R}_{MTJB +} {R}_{MTJT} ) ,$$
where R_{MTJB} is a resistance of the first stochastic magnetic tunnel junction device and R_{MTJT} is a resistance of the second stochastic magnetic tunnel junction device.

13. The random number generator of claim 12, wherein a tunnelling magnetoresistance (TMR) of each magnetic tunnel junction device is directly related to an ambient temperature of an environment surrounding the magnetic tunnel junction device, wherein each magnetic tunnel junction device is configured to generate the p-bits in response to the thermal noise at the ambient temperature.

14. The random number generator of claim 13, wherein the TMR of each of the first magnetic tunnel junction device and the second magnetic tunnel junction device is given by:
$$T M R = ( {R}_{AP} - {R}_{P} ) / {R}_{P} .$$

15. The random number generator of claim 14, wherein a stochastic range (V_{Srange}) of the p-bits at the output terminal is a function of the TMR of each magnetic tunnel junction device and is proportional to a voltage difference between the positive DC voltage V_{DD} and the negative DC voltage V_{SS}.

16. The random number generator of claim 15, wherein V_{Srange} at the voltage output Vₒᵤₜ is given by:
$${V}_{Strange} = ( ( {V}_{DD} - {V}_{SS} ) \cdot T M R ) / ( 2 + T M R ) .$$

17. The random number generator of claim 16, wherein:
the activation unit is a comparator including a non-inverting input terminal, an inverting input terminal, a source terminal, a drain terminal and a voltage output terminal,
the inverting input terminal is connected to the p-bit output terminal, and
the non-inverting input terminal is connected to the control unit, wherein the control unit is configured to generate a variable voltage V_{IN}.

18. The random number generator of claim 11, wherein the stochastic device is an electrically connected pair of superparamagnetic tunnel junction devices configured to have a p-bit response m at the p-bit output terminal given by:
$$m = sgn [ tanh ( β V ) - {r}_{U} ] ,$$
where sgn is a sign function, V is a voltage at the inverting terminal of the comparator, β is a beta factor related to a temperature inverse and r_{U} is a uniform random variable that ranges from −1 to 1.

19. The random number generator of claim 18, wherein a tunnelling magnetoresistance (TMR) of each superparamagnetic tunnel junction device is directly related to an ambient temperature of an environment surrounding the superparamagnetic tunnel junction device, wherein each superparamagnetic tunnel junction device is configured to generate the p-bits in response to the thermal noise at the ambient temperature,
wherein the TMR of each superparamagnetic tunnel junction device is given by:
$$T M R = ( {R}_{AP} - {R}_{P} ) / {R}_{P} ,$$
and
wherein the beta factor β is given by:
$$β = 2 ( T M R + 2 ) ( arctanh ( 0.99 ) / ( T M R \cdot ( {V}_{DD} - {V}_{SS} ) ) .$$

20. A method of implementing a tunable probabilistic bit (p-bit) voltage divider, comprising:
connecting a first stochastic magnetic tunnel junction device to a second stochastic magnetic tunnel junction device,
connecting a positive DC voltage V_{DD} to the first electrical terminal of the first stochastic magnetic tunnel junction device;
connecting a negative DC voltage V_{SS} connected to the second electrical terminal of the second stochastic magnetic tunnel junction device, wherein each stochastic magnetic tunnel junction device is configured to generate p-bits which randomly oscillate between a first resistance state and a second resistance state in response to thermal noise;
generating, at a p-bit output terminal comprising the second electrical terminal of the first stochastic magnetic tunnel junction device and the first electrical terminal of the second stochastic magnetic tunnel junction device, p-bit output signals;
connecting an inverting terminal of a comparator to the p-bit output terminal;
connecting a non-inverting terminal of the comparator to a variable voltage V_{IN};
increasing a voltage of the variable voltage V_{IN} until the variable voltage V_{IN} is equal to a voltage received at the inverting terminal based on the p-bit output signals; and
generating a voltage Vₒᵤₜ at the voltage output terminal given by:
$${V}_{out} = ( {V}_{DD} \cdot {R}_{MTJB} + {V}_{SS} \cdot {R}_{MTJT} ) / ( {R}_{MTJB +} {R}_{MTJT} ) ,$$
where R_{MTJB} is a resistance of the first stochastic magnetic tunnel junction device and R_{MTJT} is a resistance of the second stochastic magnetic tunnel junction device.
